(19) United States
(12) Patent Application Publication
(10) Pub. No.: US 2026/0047228 A1
(43) Pub. Date: Feb. 12, 2026

(54) FOUR-POSITION SOLAR SILICON WAFER PRINTER

(71) Applicant: Guangdong Kelongwei Automation Equipment Co., Ltd., Dongguan (CN)

(72) Inventors: Jincai SU, Dongguan (CN); Chunfu CHEN, Dongguan (CN)

(21) Appl. No.: 19/365,341

(22) Filed: Oct. 22, 2025

(30) Foreign Application Priority Data
Nov. 27, 2024 (CN) 202411717666.9

(51) Int. Cl. H10F 71/00; B41F 15/08; B41F 15/20; B41F 15/22; B41F 15/36; B41F 15/44; B41F 21/08; B41F 23/04; B41F 33/00; H04N 23/90

(52) U.S. Cl. CPC H10F 71/1375; B41F 15/0818; B41F 15/0863; B41F 15/20; B41F 15/22; B41F 15/36; B41F 15/44; B41F 21/08; B41F 23/0443; B41F 33/00; B41P 2215/11; B41P 2215/12; B41P 2215/50; H04N 23/90

(57) ABSTRACT

The present invention discloses a four-position full-cell solar silicon wafer printer, including a base, an infeed guide rail, a detection camera assembly, a turntable assembly, a lifting module, a UVW correction alignment mechanism, and an outfeed guide rail. The UVW mechanism comprises two Y-axis modules, one X-axis module, a printing platform, a steel mesh frame, and a printing squeegee kit. The Y/X-axis modules are under the platform, their drive ends connected to the steel mesh frame. The squeegee kit moves left-right on the platform. It uses the Y/X-axis modules and detection camera to realize X, Y, θ three-axis motion, ensuring steel mesh-silicon wafer alignment and optimizing printing directions.

### CROSS-REFERENCE TO RELATED APPLICATIONS

This application claims the benefit of priority from Chinese Patent Application No. 202411717666.9, field on Nov. 27, 2024. The content of the aforementioned application, including any intervening amendments thereto, is incorporated by reference in its entirety.

### TECHNICAL FIELD

The present invention relates to the technical field of silicon wafer production, particularly to a four-position full-cell solar silicon wafer printer.

### BACKGROUND

Photovoltaic solar silicon wafers constitute the core component of solar power generation systems and represent the most valuable part of solar power generation systems. The function of silicon wafers is to convert solar energy into electrical energy, and then electrical energy is stored in batteries or directly powers loads. In current printers, the X-axis (controls left-right), Y-axis (controls front-back), and T-axis (controls rotation) typically need to be coordinated to align the steel mesh with the silicon wafer. This excessive number of structures leads to poor precision. Additionally, the front-back movement of the squeegee is controlled using a motor paired with a lead screw, resulting in low efficiency and impacting the process.

### SUMMARY

One objective of the present invention is to provide a four-position full-cell solar silicon wafer printer. This design reduces the T-axis structure and utilizes two Y-axis modules and one X-axis module to handle rotation on the T-axis, thereby saving structural complexity and improving efficiency. Additionally, the lifting section adopts a novel lifting mechanism to replace a mechanism consisting of splines, ball screws, synchronizing wheels, synchronizing belts, and servo motors.

To achieve this objective, the present invention employs the following technical solutions:

A four-position full-cell solar silicon wafer printer, including a base, an infeed guide rail mounted on the base, a detection camera assembly, a turntable assembly, a lifting module, a UVW correction alignment mechanism, and an outfeed guide rail; the infeed guide rail and the outfeed guide rail are positioned on both sides of the base, the turntable assembly is located at the center of the base, the detection camera assembly is positioned above the turntable assembly, the two lifting modules are positioned on both rear sides of the turntable assembly, and the lifting modules are connected beneath the UVW correction alignment mechanism; the UVW correction alignment mechanism comprises two Y-axis modules, one X-axis module, a printing platform, a steel mesh frame, and a squeegee kit. The two Y-axis modules and one X-axis module are mounted beneath the printing platform. The drive ends of the Y-axis modules and the X-axis module are connected to the steel mesh frame. A transverse squeegee module is mounted on the printing platform, the drive end of the transverse squeegee module is connected to the printing squeegee kit, and the printing squeegee kit moves on the printing platform in the left-right direction.

As a preferred technical solution, the X-axis module and the Y-axis module utilize the same module mechanism, the module mechanism comprises a module base plate, a module motor, an adjustment lead screw, and an adjustment sliding table. The drive end of the module motor is connected to the adjustment lead screw in a transmission way, the adjustment lead screw is threadedly connected to an adjustment nut beneath the adjustment sliding table, and the adjustment sliding table slides along the length of the adjustment lead screw. A connecting bearing is arranged on the adjustment sliding table, and the connecting bearing slides along the adjustment sliding table, with the movement direction of the connecting bearing being mutually perpendicular to that of the adjustment sliding table, wherein the edge of the steel mesh frame is locked within the connecting bearing.

As a preferred technical solution, a clamping motor is mounted on the infeed guide rail, the drive end of the clamping motor being keyed to a clamping synchronizing wheel, the clamping synchronizing wheel being connected to a clamping synchronizing belt, the clamping synchronizing belt having a clamping plate fixed thereto, and the clamping plate being rotatably connected to a clamping wheel.

As a preferred technical solution, the turntable assembly comprises a circular turntable, an integrated electrical slip ring, and a turntable motor. Four positions are mounted around the periphery of the circular turntable, and each of the positions is provided with a full-cell printing position. The drive end of the turntable motor vertically connects upward to the integrated electrical slip ring, the central portion of the circular turntable connects to the integrated electrical slip ring, the lower end of the circular turntable rotatably connects to a roll paper transport component. The roll paper transport component comprises an unwinding shaft and a winding shaft. A roll paper is connected between the unwinding shaft and the winding shaft in a transmission way. The roll paper passes through the full-cell printing position and carries silicon wafers to transport silicon wafers. The roll paper is air-permeable. The roll paper transport component conveys silicon wafers to the positions on the circular turntable and transports them to the full-cell printing position.

As a preferred technical solution, the locations between the four positions of the circular turntable form sector-shaped regions. These regions, together with the central location of the circular turntable, store electrical components and control assemblies, and are covered by a protective cap. Each of the full-cell printing positions is provided with a vented vacuum plate. The vented vacuum plate is provided with a plurality of air holes, and the air holes, through a roll paper, adsorb and fix the silicon wafer at the full-cell printing position.

As a preferred technical solution, the detection camera assembly comprises an infeed vision module and an outfeed vision module. The infeed vision module is provided with one infeed camera and four mark point cameras, wherein the upper ends of the mark point cameras are adjustable along the front-to-back direction on the infeed vision module. The outfeed vision module is provided with an outfeed camera, and the upper end of the outfeed camera is adjustable along the front-to-back direction on the outfeed vision module.

As a preferred technical solution, the printing squeegee kit has a stock squeegee connected to its lower end, and a squeegee motor is mounted on the upper end of the printing squeegee kit. The squeegee motor controls the vertical movement of the stock squeegee via a ball screw and ball nut. The lower end of the printing squeegee kit is further connected to an ink reclaiming blade. The upper end of the printing squeegee kit is additionally equipped with an ink reclaiming motor. The ink reclaiming motor also controls the vertical movement of the ink reclaiming blade holder of the ink reclaiming blade via a ball screw and ball nut. Both ends of the ink reclaiming blade are respectively locked at both ends of the ink reclaiming blade holder.

As a preferred technical solution, the lifting module comprises a side bracket, a lifting servo motor is mounted at the upper end of the side bracket, and the drive end of the lifting servo motor is connected to a lifting ball screw. Both sides of the printing module are connected to lifting plates, with lifting ball nuts fixed to the outer sides of the lifting plates. The lifting ball screw is threadedly connected to the lifting ball nut, and the lifting plate slides vertically along the side bracket. The side bracket is provided with a lifting guide rail, and the outer side of the lifting plate is fixed with a lifting slider, and the lifting slider slides along the lifting guide rail.

As a preferred technical solution, a fragment lifting cylinder is mounted on the outfeed guide rail. The drive end of the fragment lifting cylinder is connected upward to a fragment lifting plate. Both sides of the fragment lifting plate are located outside the outfeed guide rail. A detection bracket is mounted at the rear end of the outfeed guide rail. A sensor is mounted on the top of the detection bracket, positioned above the outfeed guide rail. The sensor detects whether plate jams occur in the rear drying oven or firing oven.

The beneficial effects of the present invention are as follows: A four-position full-cell solar silicon wafer printer is provided. The four-position full-cell solar silicon wafer printer utilizes the movement of two Y-axis modules and one X-axis module, integrated with a detection camera assembly, to achieve rotational movement centered at any point on the plane and translational movement in any direction (X, Y, θ three-axis motion) and ensure alignment between the steel mesh and the silicon wafer, the printing difference between the left and right directions and existing front-to-back printing.

### BRIEF DESCRIPTION OF THE DRAWINGS

The present invention will now be described in further detail with reference to the drawings and embodiments.

FIG. 1 is a schematic diagram of the first structure of the four-position solar silicon wafer printer according to the embodiment;

FIG. 2 is a schematic diagram of the second structure of the four-position solar silicon wafer printer according to the embodiment;

FIG. 3 is a structural diagram of the infeed guide rail according to the embodiment;

FIG. 4 is a structural diagram of the detection camera assembly according to the embodiment;

FIG. 5 is a schematic diagram of the first structure of the turntable assembly according to the embodiment;

FIG. 6 is a schematic diagram of the second structure of the turntable assembly according to the embodiment;

FIG. 7 is a structural diagram of the turntable motor according to the embodiment;

FIG. 8 is a combined structural diagram of the UVW correction alignment mechanism and the lifting module according to the embodiment;

FIG. 9 is a structural diagram of the UVW correction alignment mechanism according to the embodiment;

FIG. 10 is an exploded view of the X-axis module according to the embodiment;

FIG. 11 is a structural diagram of the lifting module according to the embodiment;

FIG. 12 is a structural diagram of the printing squeegee kit according to the embodiment;

FIG. 13 is an exploded view of the printing squeegee kit according to the embodiment;

FIG. 14 is a structural diagram of the outfeed guide rail according to the embodiment.

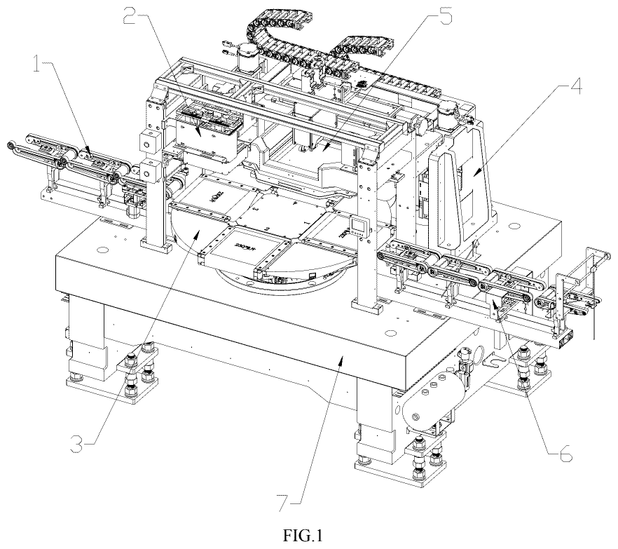

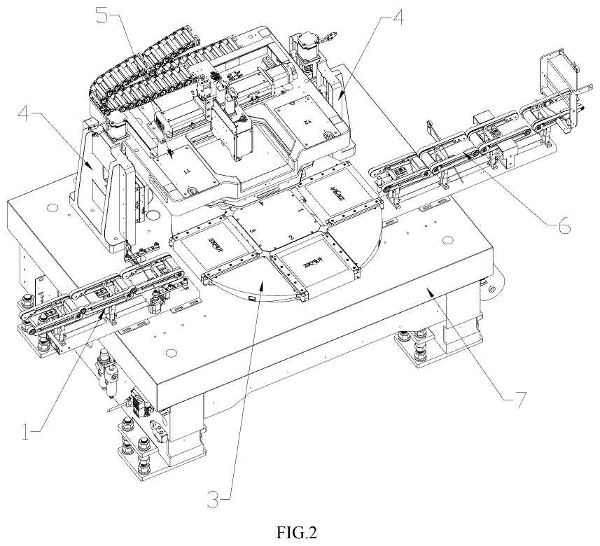

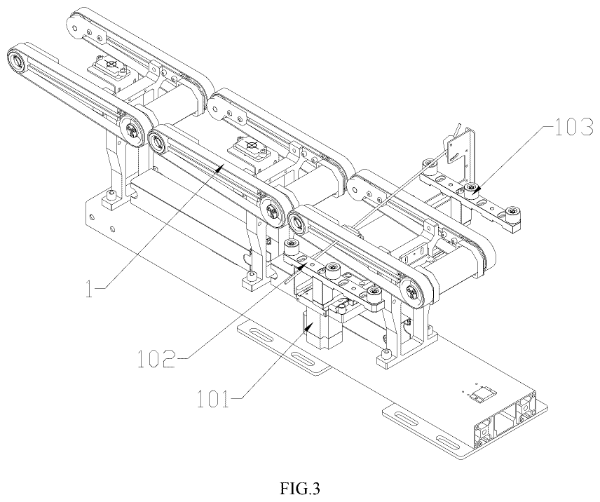

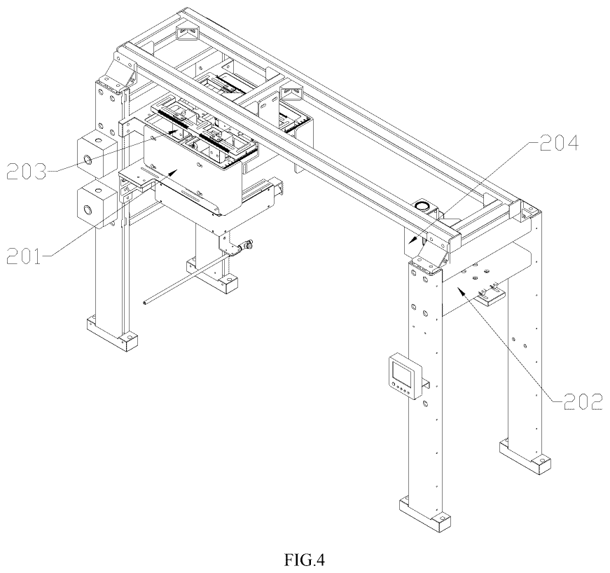

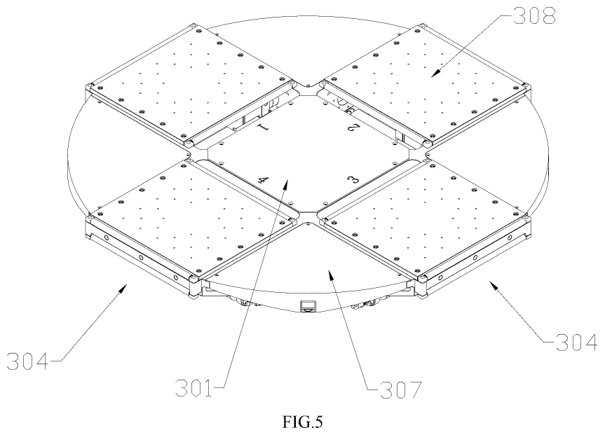

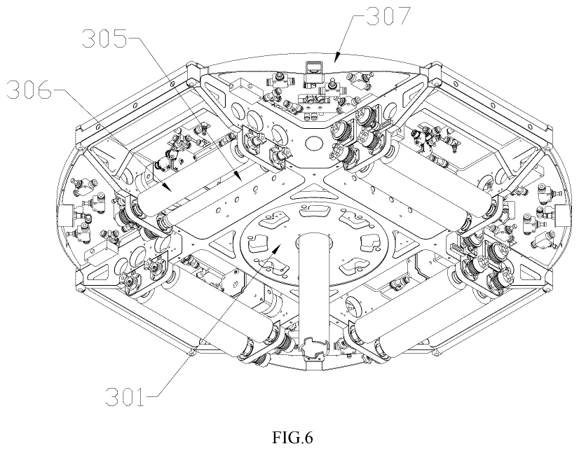

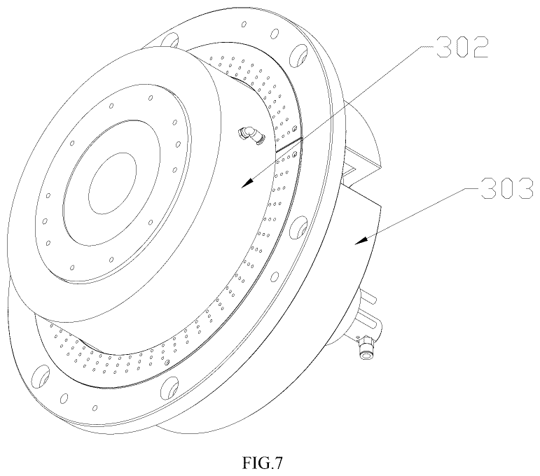

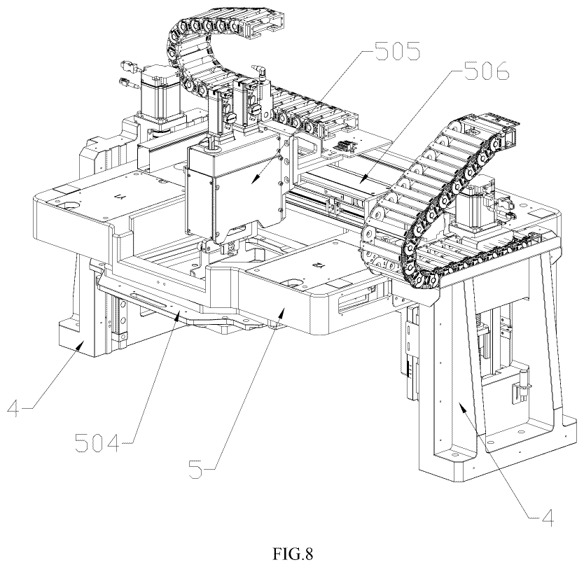

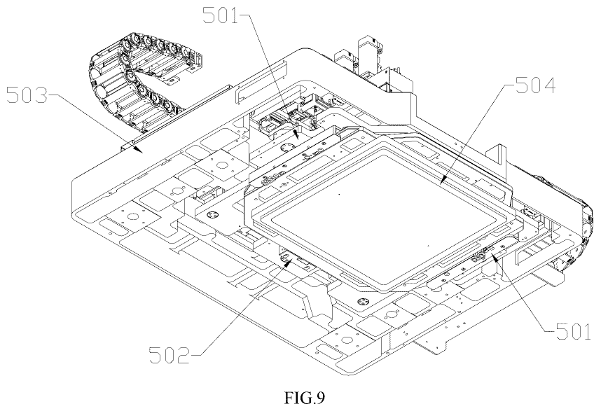

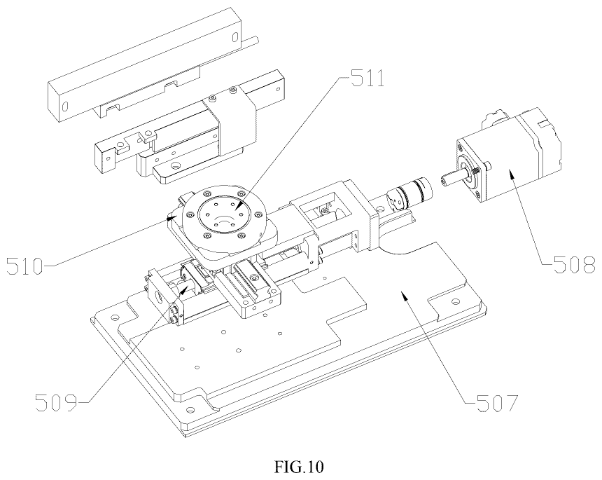

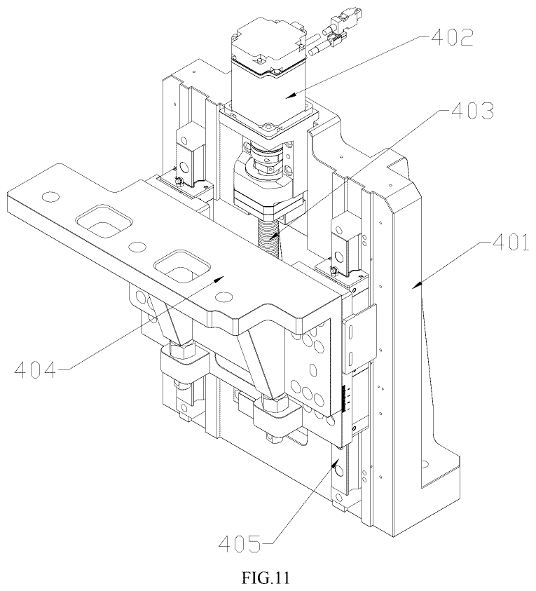

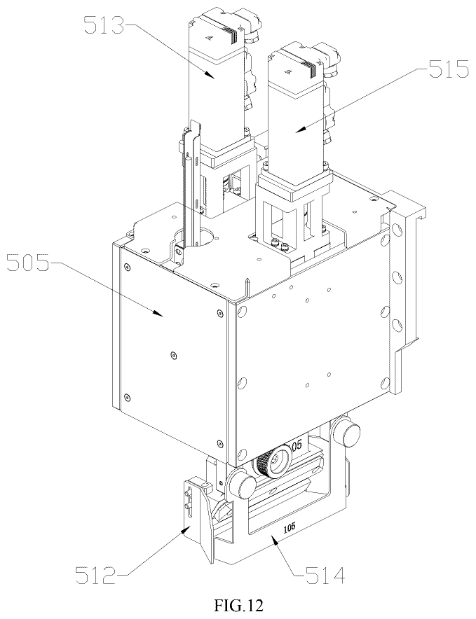

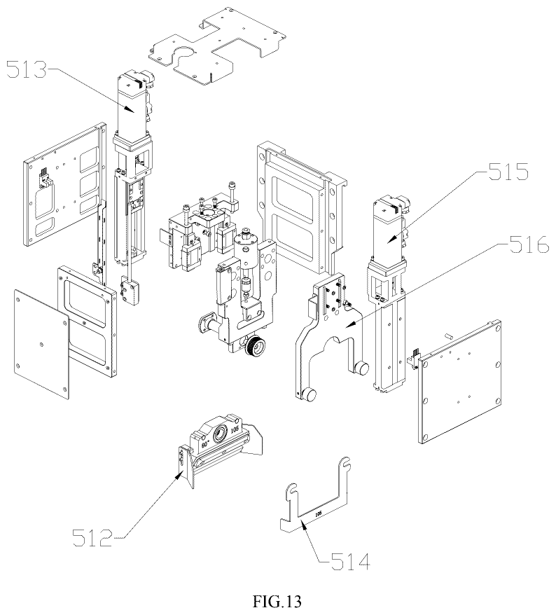

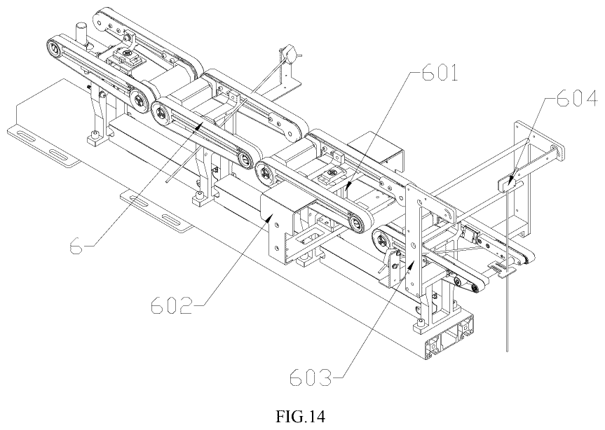

In FIGS. 1 to 14:
1. Infeed guide rail; 2. Detection camera assembly; 3. Turntable assembly; 4. Lifting module; 5. UVW correction alignment mechanism; 6. Outfeed guide rail; 7. Base;
101. Clamping motor; 102. Clamping plate; 103. Clamping wheel;
201. Infeed vision module; 202. Outfeed vision module; 203. Mark point camera;
204. Outfeed camera;
301. Circular turntable; 302. Integrated electrical slip ring; 303. Turntable motor; 304. Full-cell printing position; 305. Unwinding shaft; 306. Winding shaft; 307. Protective cap; 308. Vented vacuum plate;
401. Side bracket; 402. Lifting servo motor; 403. Lifting ball screw; 404. Lifting plate; 405. Lifting guide rail;
501. Y-axis module; 502. X-axis module; 503. Printing platform; 504. Steel mesh frame; 505. Squeegee kit; 506. Transverse squeegee module; 507. Module base plate; 508. Module motor; 509. Adjustment lead screw; 510. Adjustment sliding table; 511. Connecting bearing; 512. Stock squeegee; 513. Squeegee motor; 514. Ink reclaiming blade; 515. Reclaiming motor; 516. Ink reclaiming squeegee holder; 601. Fragment lifting cylinder; 602. Fragment lifting plate; 603. Detection bracket; 604. Sensor.

### DETAILED DESCRIPTION OF EMBODIMENTS

The technical solution of the present invention will be further explained by specific embodiments with reference to the attached drawings.

As shown in FIGS. 1 to 14, in this embodiment, a four-position full-cell solar silicon wafer printer comprises a base 7 and an infeed guide rail 1 mounted on the base 7, a detection camera assembly 2, a turntable assembly 3, a lifting module 4, a UVW correction alignment mechanism 5, and an outfeed guide rail 6; the infeed guide rail 1 and outfeed guide rail 6 are positioned on opposite sides of the base 7, the turntable assembly 3 is located at the center of the base 7, with the detection camera assembly 2 positioned above the turntable assembly 3. Two lifting modules 4 are situated on the rear sides of the turntable assembly 3, with each lifting module 4 connected beneath the UVW correction alignment mechanism 5.

The front end places the silicon wafer onto the infeed guide rail 1. The infeed guide rail 1 transfers the silicon wafer onto the turntable assembly 3, wherein the detection camera assembly 2 performs visual alignment. The turntable assembly 3 rotates the silicon wafer to the rear side. Two Y-axis modules 501 and one X-axis module 502 on the UVW correction alignment mechanism 5 control the alignment in X-axis direction, Y-axis direction, and T-axis direction, ensuring the UVW correction alignment mechanism 5 equipped with a steel mesh to align with the location of the silicon wafer. The lifting module 4 lowers the steel mesh onto the silicon wafer to scrape the stock to the silicon wafer. After raising the UVW correction alignment mechanism 5, the turntable assembly 3 transfers the silicon wafer to the outfeed guide rail 6 for output.

The UVW correction alignment mechanism 5 is a high-precision motion structure specifically designed for high-precision alignment equipment. Commonly referred to as an XXY platform, this three-axis parallel movement mechanism achieves rotational motion centered at any point on a plane and translation in any direction (in-plane three-axis X, Y, θ motion) by controlling the parallel movement of three linear motion structures. When integrated with the following vision module, the UVW correction alignment mechanism 5 delivers high-precision alignment capabilities suitable for printing applications.

More specifically, the implementation process of the UVW correction alignment mechanism 5 involves determining the transformation matrix from the camera coordinate system to the UVW platform coordinate system through visual calibration. The marker template obtains the x, y, and 0 offsets between the marker template position and the marker to be corrected (based on the origin coordinate system of the UVW correction alignment mechanism 5) based on the coordinate values of the origin coordinate system of the UVW correction alignment mechanism 5 through the visual module. Then, after the initial coordinates of the three axes are input according to the formula, the rotation center is set to (0,0), and the θ offset is input, the new coordinate values of the UVW three axes, the new coordinates of the object to be corrected, and the feed amounts corresponding to the three motors can be obtained. The series operations decompose the motion process into translation and rotation components, and calculate the motor feed amounts separately to achieve precise automatic positioning with alignment accuracy reaching the micron order.

The specific structure is as follows:
The UVW correction alignment mechanism 5 comprises two Y-axis modules 501, one X-axis module 502, a printing platform 503, a steel mesh frame 504, and a printing squeegee kit 505. Two Y-axis modules 501 and one X-axis module 502 are mounted on the lower end of the printing platform 503. The drive ends of both Y-axis modules 501 and the X-axis module 502 are connected to the steel mesh frame 504. A transverse squeegee module 506 is mounted on the printing platform 503, with its drive end connected to the printing squeegee kit 505. The printing squeegee kit 505 moves horizontally along the left-right direction on the printing platform 503.

The X-axis module 502 and Y-axis module 501 utilize identical module mechanisms. Each mechanism comprises a module base plate 507, a module motor 508, an adjustment lead screw 509, and an adjustment sliding table 510. The drive end of the module motor 508 is connected to the adjustment lead screw 509 in a transmission way. The adjustment lead screw 509 is threadedly connected to the adjustment nut beneath the adjustment sliding table 510. The adjustment sliding table 510 slides along the length of the adjustment lead screw 509. A connecting bearing 511 is provided on the adjustment sliding table 510, and the connecting bearing 511 slides on the adjustment sliding table 510. The movement direction of the connecting bearing 511 is perpendicular to the movement direction of the adjustment sliding table 510. The edge of the steel mesh frame 504 is locked within the connecting bearing 511. Two Y-axis modules 501, combined with one X-axis module 502, jointly control the T-axis rotation of one steel mesh frame 504. An auxiliary bearing is mounted on the steel mesh frame 504, and an auxiliary X-axis sliding rail is arranged on the UVW correction alignment mechanism 5. An auxiliary X-axis slider slides along the auxiliary X-axis sliding rail. An auxiliary Y-axis slider is fixed to the auxiliary X-axis slider. The auxiliary Y-axis slider is slidably connected to an auxiliary Y-axis sliding rail. The auxiliary bearing is mounted on the auxiliary Y-axis sliding rail, and together with the two X-axis modules 502 and the Y-axis module 501, adjusts the T-axis of the steel mesh frame 504.

The infeed guide rail 1 is fitted with a clamping motor 101. The drive end of the clamping motor 101 is keyed to a clamping synchronizing wheel. The clamping synchronizing wheel is connected to a clamping synchronizing belt in a transmission way. A clamping plate 102 is fixed to the clamping synchronizing belt. A clamping wheel 103 is rotatably connected to the clamping plate 102. When the position of the silicon wafer conveyed from the front is uneven, the clamping motor 101 controls the rotation of the clamping synchronizing wheel, driving the clamping synchronizing belt, causing the clamping plates 102 on both sides of the infeed guide rail 1 to converge toward the center, leveling the silicon wafer flat at the center position of the infeed guide rail 1. The clamping wheel 103 reduces the hard collision between the clamping plate 102 and the side edges of the silicon wafer.

Turntable assembly 3 comprises a circular turntable 301, an integrated electrical slip ring 302, and a turntable motor 303. Four positions are mounted around the periphery of the circular turntable 301, and each of the positions is provided with a full-cell printing position 304. The drive end of the turntable motor 303 vertically connects upward to the integrated electrical slip ring 302, the central portion of the circular turntable 301 connects to the integrated electrical slip ring 302, the lower end of the circular turntable 301 rotatably connects to a roll paper transport component. The roll paper transport component comprises an unwinding shaft 305 and a winding shaft 306. A roll paper is connected between the unwinding shaft 305 and the winding shaft 306 in a transmission way. The roll paper passes through the full-cell printing position 304 and carries silicon wafers to transport silicon wafers. The roll paper is air-permeable. The roll paper transport component conveys silicon wafers to the positions on the circular turntable 301 and transports them to the full-cell printing position 304.

The locations between the four positions of the circular turntable 301 form sector-shaped regions. These regions, together with the central location of the circular turntable 301, store electrical components and control assemblies, and are covered by a protective cap 307. Each of the full-cell printing positions 304 is provided with a vented vacuum plate 308. The vented vacuum plate 308 is provided with a plurality of air holes, and the air holes, through a roll paper, adsorb and fix the silicon wafer at the full-cell printing position 304.

The silicon wafer of the infeed guide rail 1 is placed on the full-cell printing position 304. The turntable motor 303 provides power to control the electrical slip ring 302 to synchronously rotate the circular turntable 301 horizontally, moving the silicon wafer beneath the steel mesh frame 504 while simultaneously transferring the printed silicon wafer from beneath the steel mesh frame 504 to the front of the outfeed guide rail 6. The unwinding shaft 306 rotates synchronously with the unwinding shaft 305, and clean roll paper is used to wipe the full-cell printing position 304.

The detection camera assembly 2 comprises an infeed vision module 201 and an outfeed vision module 202. The infeed vision module 201 is provided with one infeed camera and four mark point cameras 203. The four mark point cameras 203 are positioned around the perimeter of the infeed vision module 201. The infeed camera is located at the center of the infeed vision module 201 and detects fragment presence, while the mark point camera 203 detects the current position of the silicon wafer. The upper end of the mark point camera 203 is adjustable along the front-to-back direction on the infeed vision module 201. The outfeed vision module 202 is provided with an outfeed camera 204, and the upper end of the outfeed camera 204 is adjustable along the front-to-back direction on the outfeed vision module 202.

The silicon wafer conveyed from the infeed guide rail 1 is brought onto the full-cell printing position 304 under the action of the roll paper. The infeed vision module 201 above captures and locates the silicon wafer. Based on the position of silicon wafer, the steel mesh on the UVW correction alignment mechanism 5 independently adjusts in the XYT directions to meet the location requirements of silicon wafer. During outfeed, the outfeed vision module 202 again captures the printed silicon wafer. After completion, the roll paper assists in moving the silicon wafer away from the full-cell printing position 304 into the outfeed guide rail 6.

The lifting module 4 comprises a side bracket 401, a lifting servo motor 402 is mounted at the upper end of the side bracket 401, and the drive end of the lifting servo motor 402 is connected to a lifting ball screw 403. Both sides of the printing module are connected to lifting plates 404, with lifting ball nuts fixed to the outer sides of the lifting plates. The lifting ball screw 403 is threadedly connected to the lifting ball nut, and the lifting plate slides vertically along the side bracket 401. The side bracket 401 is provided with a lifting guide rail 405, and the outer side of the lifting plate 404 is fixed with a lifting slider, and the lifting slider slides along the lifting guide rail 405.

When controlling the lifting of the UVW correction alignment mechanism 5, the lifting servo motor 402 drives the lifting ball screw 403 to rotate. The lifting plate 404, equipped with the lifting ball nut, moves the UVW correction alignment mechanism 5 up and down along the lifting guide rail 405, with improved precision and faster movement speeds.

The printing squeegee kit 505 has a stock squeegee 512 connected to its lower end, and a squeegee motor 513 is mounted on the upper end of the printing squeegee kit 505. The squeegee motor 513 controls the vertical movement of the stock squeegee 512 via a ball screw and ball nut. The lower end of the printing squeegee kit 505 is further connected to an ink reclaiming blade 514. The upper end of the printing squeegee kit 505 is additionally equipped with an ink reclaiming motor 515. The ink reclaiming motor 515 also controls the vertical movement of the ink reclaiming blade holder 516 of the ink reclaiming blade 514 via a ball screw and ball nut. Both ends of the ink reclaiming blade 514 are respectively locked at both ends of the ink reclaiming blade holder 516.

During stock scraping, the squeegee motor 513 controls the stock squeegee 512 to descend onto the steel mesh. The transverse squeegee module 506 moves forward and backward, driving the printing squeegee kit 505 to move in tandem, causing the stock squeegee 512 to scrape the stock from the steel mesh onto the silicon wafer during its forward and backward motion.

A fragment lifting cylinder 601 is mounted on the outfeed guide rail 6. The drive end of the fragment lifting cylinder 601 is connected upward to a fragment lifting plate 602. Both sides of the fragment lifting plate extend beyond the outer edges of the outfeed guide rail 6. A detection bracket 603 is mounted at the rear end of the outfeed guide rail 6, with a sensor 604 mounted atop the detection bracket 603. The sensor 604 is positioned above the outfeed guide rail 6 and the sensor 604 is used to detect whether wafer jams occur in the rear drying oven or firing oven.

When transferring or detecting silicon wafers on the outfeed guide rail 6, the fragment lifting cylinder 601 raises the fragment lifting plate 602 to isolate the silicon wafer for handling. The sensor 604 at the end of the outfeed guide rail 6 detects the presence of silicon wafer to prepare for subsequent docking.

It should be noted that the above specific implementation methods merely represent preferred embodiments of the present invention and the technical principles employed. Within the scope of the disclosed technology, any modifications or substitutions readily conceivable by those skilled in the art should be encompassed within the scope of protection of the present invention.

What is claimed is:

1. A four-position full-cell solar silicon wafer printer, wherein it includes a base, an infeed guide rail mounted on the base, a detection camera assembly, a turntable assembly, a lifting module, a UVW correction alignment mechanism, and an outfeed guide rail; the infeed guide rail and the outfeed guide rail are positioned on both sides of the base, the turntable assembly is located at the center of the base, the detection camera assembly is positioned above the turntable assembly, the two lifting modules are positioned on both rear sides of the turntable assembly, and the lifting modules are connected beneath the UVW correction alignment mechanism; the UVW correction alignment mechanism comprises two Y-axis modules, one X-axis module, a printing platform, a steel mesh frame, and a squeegee kit; the two Y-axis modules and one X-axis module are mounted beneath the printing platform; the drive ends of the Y-axis modules and the X-axis module are connected to the steel mesh frame; a transverse squeegee module is mounted on the printing platform, the drive end of the transverse squeegee module is connected to the printing squeegee kit, and the printing squeegee kit moves on the printing platform in the left-right direction;
the turntable assembly comprises a circular turntable, an integrated electrical slip ring, and a turntable motor; Four positions are mounted around the periphery of the circular turntable, and each of the positions is provided with a full-cell printing position; the drive end of the turntable motor vertically connects upward to the integrated electrical slip ring, the central portion of the circular turntable connects to the integrated electrical slip ring, the lower end of the circular turntable rotatably connects to a roll paper transport component; the roll paper transport component comprises an unwinding shaft and a winding shaft; a roll paper is connected between the unwinding shaft and the winding shaft in a transmission way; the roll paper passes through the full-cell printing position and carries silicon wafers to transport silicon wafers; The roll paper is air-permeable; the roll paper transport component conveys silicon wafers to the positions on the circular turntable and transports them to the full-cell printing position;
a fragment lifting cylinder is mounted on the outfeed guide rail; the drive end of the fragment lifting cylinder is connected upward to a fragment lifting plate; both sides of the fragment lifting plate extend beyond the outer edges of the outfeed guide rail; a detection bracket is mounted at the rear end of the outfeed guide rail, with a sensor mounted atop the detection bracket; the sensor is positioned above the outfeed guide rail and the sensor is used to detect whether wafer jams occur in the rear drying oven or firing oven.

2. A four-position full-cell solar silicon wafer printer as claimed in claim 1, wherein the X-axis module and the Y-axis module utilize the same module mechanism, the module mechanism comprises a module base plate, a module motor, an adjustment lead screw, and an adjustment sliding table; the drive end of the module motor is connected to the adjustment lead screw in a transmission way, the adjustment lead screw is threadedly connected to an adjustment nut beneath the adjustment sliding table, and the adjustment sliding table slides along the length of the adjustment lead screw; a connecting bearing is arranged on the adjustment sliding table, and the connecting bearing slides along the adjustment sliding table, with the movement direction of the connecting bearing being mutually perpendicular to that of the adjustment sliding table, wherein the edge of the steel mesh frame is locked within the connecting bearing.

3. A four-position full-cell solar silicon wafer printer as claimed in claim 1, wherein a clamping motor is mounted on the infeed guide rail, the drive end of the clamping motor being keyed to a clamping synchronizing wheel, the clamping synchronizing wheel being connected to a clamping synchronizing belt, the clamping synchronizing belt having a clamping plate fixed thereto, and the clamping plate being rotatably connected to a clamping wheel;

4. A four-position full-cell solar silicon wafer printer as claimed in claim 1, wherein the locations between the four positions of the circular turntable form sector-shaped regions; these regions, together with the central location of the circular turntable, store electrical components and control assemblies, and are covered by a protective cap; each of the full-cell printing positions is provided with a vented vacuum plate; the vented vacuum plate is provided with a plurality of air holes, and the air holes, through a roll paper, adsorb and fix the silicon wafer at the full-cell printing position.

5. A four-position full-cell solar silicon wafer printer as claimed in claim 1, wherein the detection camera assembly comprises an infeed vision module and an outfeed vision module; the infeed vision module is provided with one infeed camera and four mark point cameras, wherein the upper ends of the mark point cameras are adjustable along the front-to-back direction on the infeed vision module; the outfeed vision module is provided with an outfeed camera, and the upper end of the outfeed camera is adjustable along the front-to-back direction on the outfeed vision module;

6. A four-position full-cell solar silicon wafer printer as claimed in claim 1, wherein the printing squeegee kit has a stock squeegee connected to its lower end, and a squeegee motor is mounted on the upper end of the printing squeegee kit; the squeegee motor controls the vertical movement of the stock squeegee via a ball screw and ball nut; the lower end of the printing squeegee kit is further connected to an ink reclaiming blade; the upper end of the printing squeegee kit is additionally equipped with an ink reclaiming motor; the ink reclaiming motor also controls the vertical movement of the ink reclaiming blade holder of the ink reclaiming blade via a ball screw and ball nut; both ends of the ink reclaiming blade are respectively locked at both ends of the ink reclaiming blade holder.

7. A four-position full-cell solar silicon wafer printer as claimed in claim 1, wherein the lifting module comprises a side bracket, a lifting servo motor is mounted at the upper end of the side bracket, and the drive end of the lifting servo motor is connected to a lifting ball screw; both sides of the UVW correction alignment mechanism are connected to lifting plates, with lifting ball nuts fixed to the outer sides of the lifting plates; the lifting ball screw is threadedly connected to the lifting ball nut, and the lifting plate slides vertically along the side bracket; the side bracket is provided with a lifting guide rail, and the outer side of the lifting plate is fixed with a lifting slider, and the lifting slider slides along the lifting guide rail.
